(19) United States
(12) Patent Application Publication
(10) Pub. No.: US 2012/0133860 A1
(43) Pub. Date: May 31, 2012

(54) ACTIVE MATRIX SUBSTRATE, LIQUID CRYSTAL DISPLAY PANEL, LIQUID CRYSTAL DISPLAY DEVICE, AND METHOD FOR MANUFACTURING ACTIVE MATRIX SUBSTRATE

(75) Inventors: Toshihide Tsubata, Osaka-shi (JP); Kohichi Yamashiki, Osaka-shi (JP); Mitsuhiro Sugimoto, Osaka-shi (JP); Yasuhiro Nakatake, Osaka-shi (JP)

(73) Assignee: SHARP KABUSHIKI KAISHA, Osaka-shi, Osaka (JP)

(21) Appl. No.: 13/388,513

(22) PCT Filed: Jun. 11, 2010
(86) PCT No.: PCT/JP2010/059962

§ 371 Date: Feb. 2, 2012

(30) Foreign Application Priority Data
Aug. 4, 2009 (JP) 2009-181659

(51) Int. Cl. G02F 1/1335; H01L 33/50; G02F 1/1339; H01L 27/15

(52) U.S. Cl. 349/61; 257/59; 438/29; 349/153; 257/E27.121; 257/E33.061

(57) ABSTRACT

An active matrix substrate is provided with a lead wire led out from a switching element to a surrounding region; a pad portion formed in the lead wire, and positioned in surrounding region; an insulation layer formed so as to cover pad portion, including a passivation film formed of an inorganic material, and a planarization film positioned on passivation film and formed of an organic material, and having a contact hole formed so as to reach pad; and an ITO film positioned in contact hole, and formed on pad. ITO film is formed so as to be spaced from a part defined by planarization film in an inner periphery surface of contact hole.

### TECHNICAL FIELD

The present invention relates to an active matrix substrate, a liquid crystal display panel, a liquid crystal display device, and a method for manufacturing the active matrix substrate.

### BACKGROUND ART

Conventionally, various kinds of active matrix substrates and liquid crystal display devices have been proposed.

For example, as disclosed in Japanese Patent Laying-Open No. 9-197433 (Patent Literature 1), an active matrix substrate is provided with a substrate, a gate electrode and a gate pad formed on the substrate, and an insulation film formed so as to cover the gate electrode and the gate pad, and including a silicon nitride film.

Furthermore, the active matrix substrate is provided with a semiconductor film formed on the insulation film on the gate electrode, a source electrode and a drain electrode formed on the semiconductor film, and a protective film formed so as to cover the source electrode, the drain electrode, and the insulation film positioned on the gate pad.

In addition, the active matrix substrate is provided with a contact hole formed so as to penetrate the protective film and the insulation film, and reach the gate pad, and an ITO (Indium Tin Oxide) film formed so as to reach an upper surface of the protective film from the gate pad positioned in a bottom portion of the contact hole.

### CITATION LIST

### Patent Literature

PTL 1: Japanese Patent Laying-Open No. 9-197433

### SUMMARY OF INVENTION

### Technical Problem

According to the above active matrix substrate, typically, the protective film positioned outermost is formed of an organic material and the insulation film formed on the gate pad is formed of an inorganic material. Therefore, it is difficult to ensure adherability between the protective film and the insulation film. When the protective film formed of an organic material is removed, the ITO film attached to the protective film is removed together with the protective film.

When a piece of the protective film with the ITO film attached is attached to the active matrix substrate again, short circuit could be generated depending on the attached area.

The present invention was made in view of the above problem, and it is an object of the present invention to provide an active matrix substrate, a liquid crystal display panel, a liquid crystal display device, and a method for manufacturing the active matrix substrate in which a defect such as short circuit is prevented from being generated.

### Solution to Problem

An active matrix substrate according to the present invention is provided with a substrate including a pixel array region where switching elements are arranged, and a surrounding region positioned around the pixel array region; a lead wire led out from the switching element to the surrounding region; and a pad portion formed in the lead wire, and positioned in the surrounding region.

Furthermore, the active matrix substrate is provided with an insulation layer formed so as to cover the pad portion, including an inorganic insulation film formed of an inorganic material, and an organic insulation film positioned on the inorganic insulation film and formed of an organic material, and having a contact hole formed so as to reach the pad portion; and a conductive film positioned in the contact hole, and formed on the pad portion. The conductive film is formed so as to be spaced from a part defined by the organic insulation film in an inner periphery surface of the contact hole.

Preferably, the conductive film is formed so as to be spaced from the inner periphery surface of the contact hole. Preferably, a first hole portion for defining a part of the contact hole is formed in the organic insulation film, and a second hole portion for defining another part of the contact hole is formed in the inorganic insulation film. The conductive film is formed so as to reach an inner periphery surface of the second hole portion from the pad portion.

Preferably, the second hole portion and an upper surface of the inorganic insulation film are positioned in the first hole portion when the organic insulation film and the inorganic insulation film are viewed from an extending direction of the contact hole. The conductive film is formed so as to reach the upper surface of the inorganic insulation film positioned in the first hole portion.

Preferably, the organic insulation film is formed so as to cover the switching element formed in the pixel array region, and a thickness of the organic insulation film in the part for defining the contact hole is formed so as to be smaller than a thickness of the organic insulation film in the part positioned in the pixel array region.

Preferably, the lead wire includes a first lead wire and a second lead wire arranged at a distance from each other in one direction, and the pad portion includes a first pad portion formed in the first lead wire, and a second pad portion formed in the second lead wire. The insulation layer includes a first covering portion for covering the first pad portion, and a second covering portion for covering the second pad portion, and a first contact hole is formed so as to reach the first pad portion in the first covering portion, and a second contact hole is formed so as to reach the second pad portion in the second covering portion. The first covering portion and the second covering portion are formed at a distance from each other.

Preferably, the first covering portion and the second covering portion are connected to each other on a side closer to the pixel array region than the first contact hole and the second contact hole.

Preferably, the organic insulation film serves as a color film, the insulation layer includes a protective film formed on the organic insulation film, and the organic insulation film and the protective film are formed on the pad portion and in the pixel array region.

A liquid crystal display panel according to the present invention is provided with the above active matrix substrate; an opposed substrate arranged at a distance so as to be opposed to the active matrix substrate; and a liquid crystal layer sealed between the opposed substrate and the active matrix substrate.

A liquid crystal display device according to the present invention is provided with the liquid crystal display panel; a first polarization plate arranged on an opposite side of the liquid crystal layer with respect to the active matrix substrate; a second polarization plate arranged on an opposite side of the liquid crystal layer with respect to the opposed substrate; and a backlight unit irradiating the liquid crystal display panel with light.

A method for manufacturing an active matrix substrate according to the present invention is provided with the steps of preparing a substrate including a first region serving as a pixel array region and a second region serving as a surrounding region; forming a gate electrode in the first region, a pad portion in the second region, and a lead wire for connecting the gate electrode and the pad portion; and forming an inorganic insulation film on the substrate. Furthermore, the method is provided with the steps of forming a semiconductor film on the inorganic insulation film so as to be positioned above the gate electrode; forming a first electrode on the semiconductor film; forming a second electrode on the semiconductor film so as to be positioned at a distance from the first electrode; and forming an organic insulation film for covering the first electrode and the second electrode. Furthermore, the method is provided with the steps of forming a contact hole so as to penetrate the organic insulation film and the inorganic insulation film positioned in the second region, and reach the pad portion positioned in the second region; and forming a conductive film on an upper surface of the pad portion positioned in a bottom portion of the contact hole so as to be positioned at a distance from a part defined by the organic insulation film in an inner periphery surface of the contact hole.

Preferably, the method is further provided with the step of lowering a height of the organic insulation film in the second region compared to a height of the organic insulation film in the first region.

Preferably, the organic insulation film serves as a color film, a step of forming a protective film on the organic insulation film is further provided, and the contact hole is formed after the protective film has been formed.

An active matrix substrate according to the present invention is provided with a substrate including a pixel array region where switching elements are arranged, and a surrounding region positioned around the pixel array region; a lead wire led out from the switching element to the surrounding region; a pad portion formed in the lead wire, and positioned in the surrounding region; an insulation layer including a first insulation film positioned as an uppermost layer, and a second insulation film positioned under the first insulation film, formed so as to cover the pad portion, and having a contact hole formed so as to reach the pad portion; and a conductive film positioned in the contact hole, and formed on the pad portion. The conductive film is formed so as to be spaced from the first insulation film.

Preferably, a first hole portion for defining a part of the contact hole is formed in the first insulation film, and a second hole portion for defining another part of the contact hole is formed in the second insulation film. The conductive film is formed so as to reach an inner surface of the second hole portion from the pad portion.

Preferably, the second hole portion and an upper surface of the second insulation film are positioned in the first hole portion when the first insulation film and the second insulation film are viewed from an extending direction of the contact hole, and the conductive film is formed so as to reach the upper surface of the second insulation film positioned in the first hole portion.

Preferably, the first insulation film is formed so as to cover the switching element formed in the pixel array region, and a thickness of the first insulation film in a part for defining the contact hole is formed so as to be smaller than a thickness of the first insulation film in a part positioned in the pixel array region.

Preferably, the lead wire includes a first lead wire and a second lead wire arranged at a distance from each other in one direction, the pad portion includes a first pad portion formed in the first lead wire, and a second pad portion formed in the second lead wire, and the insulation layer includes a first covering portion for covering the first pad portion, and a second covering portion for covering the second pad portion. A first contact hole is formed so as to reach the first pad portion in the first covering portion, and a second contact hole is formed so as to reach the second pad portion in the second covering portion. The first covering portion and the second covering portion are formed at a distance from each other.

Preferably, the first covering portion and the second covering portion are connected to each other on a side closer to the pixel array region than the first contact hole and the second contact hole.

According to another aspect, an active matrix substrate according to the present invention is provided with a substrate including a pixel array region where switching elements are arranged, and a surrounding region positioned around the pixel array region; a lead wire led out from the switching element to the surrounding region; a pad portion formed in the lead wire, and positioned in the surrounding region; an insulation layer formed to cover the pad portion, and having a contact hole formed so as to reach the pad portion; and a conductive film positioned in the contact hole, and formed on the pad portion. The conductive film is formed at a distance from an inner periphery surface of the contact hole.

Preferably, the first insulation film is formed so as to cover the switching element formed in the pixel array region. A thickness of the first insulation film in the part for defining the contact hole is formed so as to be smaller than a thickness of the first insulation film in the part positioned in the pixel array region.

Preferably, the lead wire includes a first lead wire and a second lead wire arranged at a distance from each other in one direction, and the pad portion includes a first pad portion formed in the first lead wire, and a second pad portion formed in the second lead wire. The insulation layer includes a first covering portion for covering the first pad portion, and a second covering portion for covering the second pad portion. A first contact hole is formed so as to reach the first pad portion in the first covering portion, and a second contact hole is formed so as to reach the second pad portion in the second covering portion, and the first covering portion and the second covering portion are formed at a distance from each other.

Preferably, the first covering portion and the second covering portion are connected to each other on a side closer to the pixel array region than the first contact hole and the second contact hole.

Preferably, the insulation layer includes an insulation film formed on the pad portion, a color film formed on the insulation film, and a protective film formed on the color film. The color film and the protective film are formed on the pad portion and in the pixel array region.

A liquid crystal display panel according to the present invention is provided with the active matrix substrate; an opposed substrate arranged at a distance so as to be opposed to the active matrix substrate; and a liquid crystal layer sealed between the opposed substrate and the active matrix substrate.

A liquid crystal display device according to the present invention is provided with the above liquid crystal display panel; a first polarization plate arranged on an opposite side of the liquid crystal layer with respect to the active matrix substrate; a second polarization plate arranged on an opposite side of the liquid crystal layer with respect to the opposed substrate; and a backlight unit irradiating the liquid crystal display panel with light.

A method for manufacturing an active matrix substrate according to the present invention is provided with the steps of preparing a substrate including a first region serving as a pixel array region and a second region serving as a surrounding region, and forming a gate electrode in the first region, a pad portion in the second region, and a lead wire for connecting the gate electrode and the pad portion. Furthermore, the method for manufacturing the active matrix substrate is provided with the steps of forming a gate insulation film on the substrate; forming a semiconductor film on the gate insulation film so as to be positioned above the gate electrode; and forming a first electrode on the semiconductor film. In addition, the method for manufacturing an active matrix substrate is provided with the steps of forming a second electrode on the semiconductor film so as to be positioned at a distance from the first electrode; forming an interlayer insulation film including an uppermost insulation film serving as an uppermost layer so as to cover the first electrode and the second electrode; and forming a contact hole so as to penetrate the interlayer insulation film and the gate insulation film, and reach the pad portion in the second region. In addition, the method is provided with the step of forming a conductive film on an upper surface of the pad portion positioned in a bottom portion of the contact hole so as to be positioned at a distance from a part defined by the uppermost insulation film in an inner periphery surface of the contact hole.

Preferably, the method is further provided with the step of lowering a height of the interlayer insulation film in the second region compared to a height of the interlayer insulation film in the first region.

According to another aspect, a method for manufacturing an active matrix substrate according to the present invention is provided with the steps of preparing a substrate including a first region serving as a pixel array region and a second region serving as a surrounding region; forming a gate electrode in the first region, a pad portion in the second region, and a lead wire for connecting the gate electrode and the pad portion; and forming a gate insulation film on the substrate. Furthermore, the method is provided with the steps of forming a semiconductor film on the gate insulation film so as to be positioned above the gate electrode; forming a first electrode on the semiconductor film; and forming a second electrode on the semiconductor film so as to be positioned at a distance from the first electrode. Furthermore, the method is provided with the steps of forming an interlayer insulation film so as to cover the first electrode and the second electrode; forming a contact hole so as to penetrate the interlayer insulation film and the gate insulation film, and reach the pad portion in the second region; and forming a conductive film on an upper surface of the pad portion positioned in a bottom portion of the contact hole so as to be positioned at a distance from an inner periphery surface of the contact hole.

Preferably, the interlayer insulation film serves as a color film, a step of forming a protective film on the interlayer insulation film is further provided, and the contact hole is formed after the protective film has been formed.

### Advantageous Effects of Invention

According to the active matrix substrate, the liquid crystal display panel, the liquid crystal display device, and the method for manufacturing the active matrix substrate in the present invention, the defect such as short circuit can be prevented from being generated.

### BRIEF DESCRIPTION OF DRAWINGS

FIG. 1 is an exploded perspective view showing a configuration of a television receiver 500 according to a first embodiment of the present invention.

FIG. 2 is a perspective view schematically showing a liquid crystal display device 300.

FIG. 3 is a plan view schematically showing a liquid crystal display element 200.

FIG. 4 is an exploded perspective view showing an arrangement state of a liquid crystal display panel 101 and a polarization plate 156.

FIG. 5 is a plan view of liquid crystal display panel 101.

FIG. 6 is a circuit diagram showing a thin film transistor array formed on an active matrix substrate 130.

FIG. 7 is a cross-portional view of liquid crystal display panel 101 in a display region 103.

FIG. 8 is a cross-portional view of active matrix substrate 130 showing a detail of a thin film transistor 115.

FIG. 9 is a cross-portional view of a gate pad 112 formed in a surrounding region 105.

FIG. 10 is a cross-portional view showing a variation of gate pad 112.

FIG. 11 is a plan view showing gate pads 112 formed in surrounding region 105.

FIG. 12 is a cross-portional view showing a first manufacturing step of steps for manufacturing active matrix substrate 130, and a cross-portional view in display region 103.

FIG. 13 is a cross-portional view showing the first step of the steps for manufacturing active matrix substrate 130, and a cross-portional view in surrounding region 105.

FIG. 14 shows a manufacturing step after the manufacturing step shown in FIGS. 12 and 13, and is a cross-portional view in display region 103.

FIG. 15 is a cross-portional view in surrounding region 105 in the manufacturing step shown in FIG. 14.

FIG. 16 shows a manufacturing step after the manufacturing step shown in FIGS. 14 and 15, and is a cross-portional view in display region 103.

FIG. 17 is a cross-portional view in surrounding region 105 in the manufacturing step shown in FIG. 16.

FIG. 18 shows a manufacturing step after the manufacturing step shown in FIGS. 16 and 17, and is a cross-portional view in display region 103.

FIG. 19 is a cross-portional view in surrounding region 105 in the manufacturing step shown in FIG. 18.

FIG. 20 shows a manufacturing step after the manufacturing step shown in FIGS. 18 and 19, and is a cross-portional view in display region 103.

FIG. 21 is a cross-portional view in surrounding region 105 in the manufacturing step shown in FIG. 20.

FIG. 22 is a cross-portional view of liquid crystal display 101 in surrounding region 105 according to a second embodiment of the present invention.

FIG. 23 is a cross-portional view showing gate pad 112 and its periphery, and a cross-portional view when gate pad 112 is viewed in a long-side direction.

FIG. 24 is a cross-portional view showing a variation of liquid crystal display panel 101 according to this embodiment.

FIG. 25 is a cross-portional view showing a state in which after gate pad 112 and a gate insulation film 133 have been formed on an upper surface of a transparent substrate 131, a passivation film 137 and an insulation film 238 are formed in surrounding region 105.

FIG. 26 is a cross-portional view in display region 103 in the state shown in FIG. 25.

FIG. 27 shows a manufacturing step after the manufacturing step shown in FIGS. 25 and 26, and is a cross-portional view in surrounding region 105.

FIG. 28 is a cross-portional view in display region 103 in the manufacturing step shown in FIG. 27.

FIG. 29 shows a manufacturing step after the manufacturing step shown in FIGS. 27 and 28, and is a cross-portional view in surrounding region 105.

FIG. 30 is a cross-portional view in display region 103 in the manufacturing step shown in FIG. 29.

FIG. 31 is a cross-portional view of liquid crystal display 101 in display region 103 according to a third embodiment of the present invention.

FIG. 32 is a cross-portional view of liquid crystal display 101 in surrounding region 105 according to the third embodiment of the present invention.

FIG. 33 shows a state in which a gate electrode 132, gate insulation film 133, a semiconductor layer 134, a source electrode 135, and a drain electrode 136 have been formed on transparent substrate 131, and is a cross-portional view in display region 103.

FIG. 34 is a cross-portional view in surrounding region 105 in the state shown in FIG. 33.

FIG. 35 shows a manufacturing step after the manufacturing step shown in FIGS. 33 and 34, and is a cross-portional view in display region 103.

FIG. 36 is a cross-portional view in surrounding region 105 in the manufacturing step shown in FIG. 35.

FIG. 37 shows a manufacturing step after the manufacturing step shown in FIGS. 35 and 36, and is a cross-portional view in display region 103.

FIG. 38 is a cross-portional view in surrounding region 105 in the manufacturing step shown in FIG. 37.

FIG. 39 is a cross-portional view of liquid crystal display 101 in surrounding region 105 according to a fourth embodiment of the present invention.

FIG. 40 is a cross-portional view showing a variation of surrounding region 105 shown in FIG. 39.

FIG. 41 is a cross-portional view of a source pad 114 and its periphery of liquid crystal display 101 according to a fifth embodiment of the present invention.

FIG. 42 is cross-portional view taken along a line XLII-XLII in FIG. 41.

FIG. 43 is a cross-portional view of a region for forming source pad 114, in the first manufacturing step of active matrix substrate 130 shown in FIGS. 12 and 13.

FIG. 44 is a cross-portional view of the region for forming source pad 114, in the manufacturing step shown in FIGS. 14 and 15.

FIG. 45 is a cross-portional view of the region for forming source pad 114, in the manufacturing step shown in FIGS. 16 and 17.

FIG. 46 is a cross-portional view of the region for forming source pad 114, in the manufacturing step shown in FIGS. 18 and 19.

FIG. 47 shows a manufacturing step after the manufacturing step shown in FIG. 46, and is a cross-portional view of the region for forming source pad 114.

FIG. 48 shows a manufacturing step after the manufacturing step shown in FIG. 47, and is a cross-portional view of the region for forming source pad 114.

### DESCRIPTION OF EMBODIMENTS

A description will be made of an active matrix substrate, a liquid crystal display panel, a liquid crystal display device, a television receiver, and a method for manufacturing the active matrix substrate according to the present invention, with reference to FIGS. 1 to 48.

### First Embodiment

FIG. 1 is an exploded perspective view showing a configuration of a television receiver 500 according to a first embodiment of the present invention. As shown in FIG. 1, television receiver 500 is provided with a casing 181 arranged on a front side, a casing 182 arranged on a rear side, a liquid crystal display device 300 arranged between casing 181 and casing 182, an operating circuit 184, and a supporting member 185.

Liquid crystal display device 300 is enclosed by casing 181 and casing 182, and sandwiched between casing 181 and casing 182.

An opening portion 183 is formed in casing 181, and an image displayed on liquid crystal display device 300 can be externally seen through. Operating circuit 184 is provided in casing 182 to operate liquid crystal display device 300. Casing 182 is supported by supporting member 185.

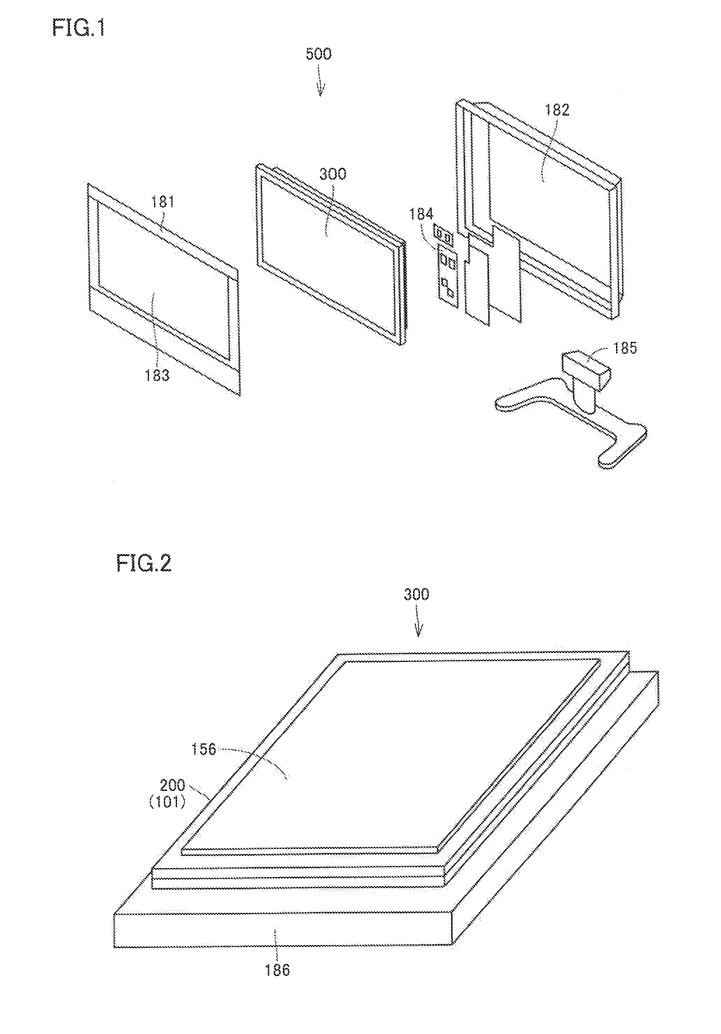

FIG. 2 is a perspective view schematically showing liquid crystal display device 300. As shown in FIG. 2, liquid crystal display device 300 is provided with a liquid crystal display element 200 including a liquid crystal display panel 101, a polarization plate 156 mounted on one main surface of liquid crystal display panel 101, a polarization plate mounted on the other main surface of liquid crystal display panel 101, and a backlight unit 186 to irradiate liquid crystal display panel 101 with light.

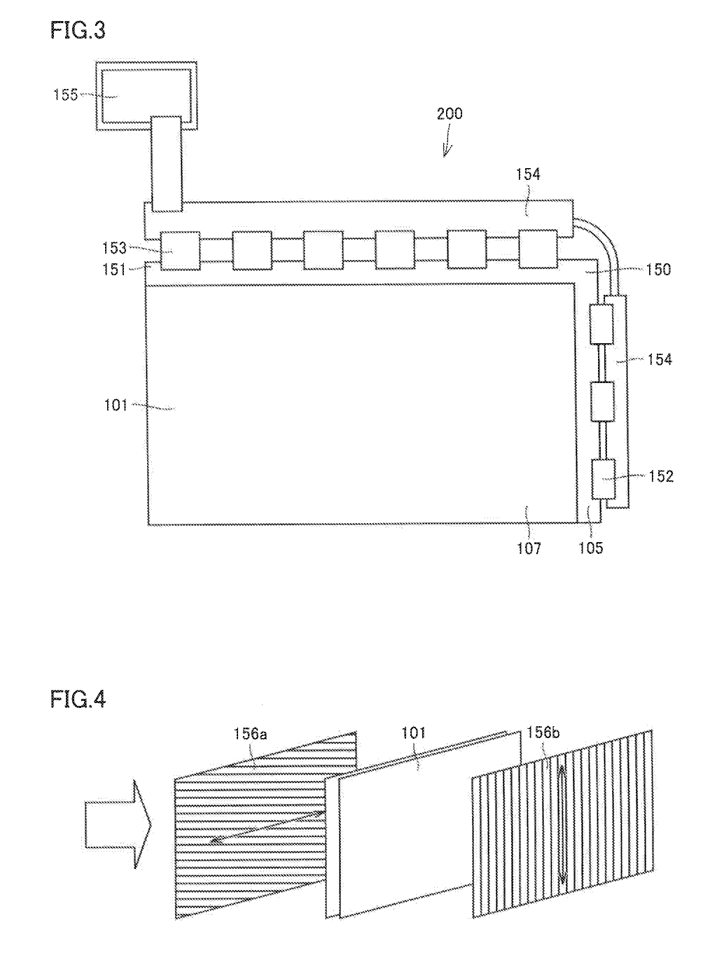

FIG. 3 is a plan view schematically showing liquid crystal display element 200. As shown in FIG. 3, liquid crystal display element 200 includes liquid crystal display panel 101, a gate driver 152 connected to a gate terminal portion 150 of liquid crystal display panel 101, a source driver 153 connected to a source terminal portion 151 of liquid crystal display panel 101, a printed substrate wire 154 connected to gate driver 152 and source driver 153, and a display control circuit 155 connected to printed substrate wire 154.

FIG. 4 is an exploded perspective view showing an arrangement state of liquid crystal display panel 101 and polarization plate 156. As shown in FIG. 4, a polarization plate 156a is mounted on one main surface of liquid crystal display panel 101, and another polarization plate 156b is mounted on the other main surface of liquid crystal display panel 101.

Note that a polarizing axis direction of polarization plate 156a and a polarizing axis direction of polarization plate 156b are formed so as to intersect with each other. Light from backlight unit 186 shown in FIG. 2 is emitted toward polarization plate 156a.

Liquid crystal panel 101 includes an active matrix substrate, an opposed substrate arranged at a distance so as to be opposed to the active matrix substrate, and a liquid crystal layer sealed between the active matrix substrate and the opposed substrate. Thus, polarization plate 156a is arranged on the opposite side of the liquid crystal layer with respect to the active matrix substrate, and polarization plate 156b is arranged on the opposite side of the liquid crystal layer with respect to the opposed substrate.

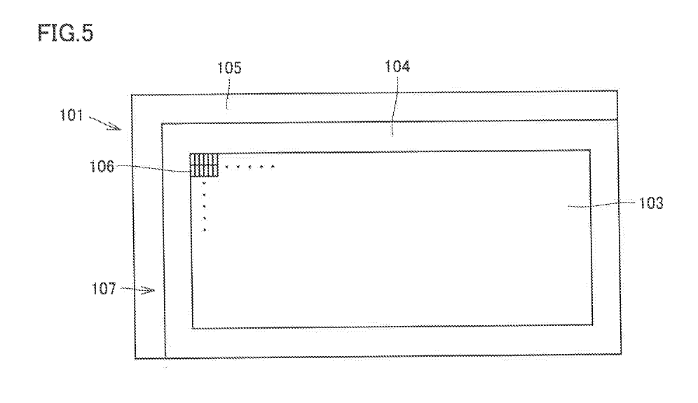

FIG. 5 is a plan view of liquid crystal display panel 101. As shown in FIG. 5, liquid crystal display panel 101 includes a pixel array region 107 including a display region 103 and a non-display region 104, and a surrounding region 105 provided around pixel array region 107.

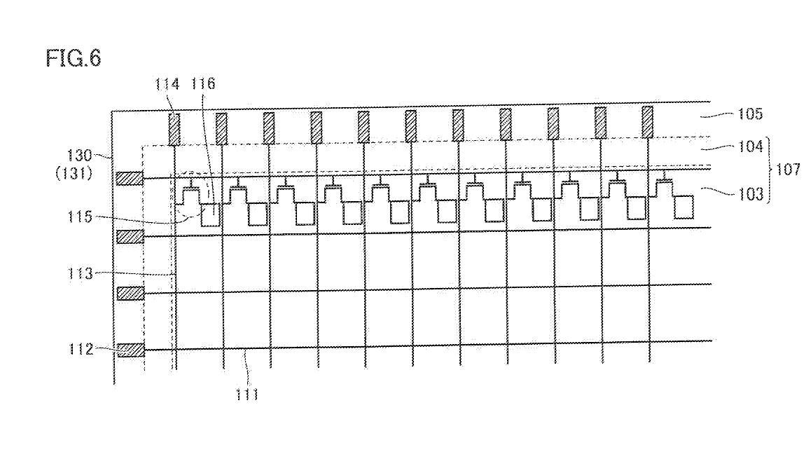

Display region 103 is provided to display an image, and includes a plurality of pixels. Non-display region 104 does not display the image, and is arranged around display region 103. FIG. 6 is a circuit diagram showing a thin film transistor array formed in an active matrix substrate 130.

Active matrix substrate 130 is provided with a transparent substrate 131 including pixel array region 107 and surrounding region 105 positioned around pixel array region 107.

A plurality of thin film transistors (switching elements) 115 are arranged in display region 103 of pixel array region 107 on a main surface of transparent substrate 131. Gate lines (lead lines) 111 connected to gate electrodes of thin film transistors 115 and data lines (lead lines) 113 connected to source electrodes of thin film transistors 115 are formed on active matrix substrate 130. A pixel electrode 116 is connected to a drain electrode of thin film transistor 115.

In general, active matrix substrate 130 has a rectangular shape. Gate lines 111 extend in a longitudinal direction of active matrix substrate 130, and gate lines 11 are formed at a distance from each other in a shorter-side direction of active matrix substrate 130. Data lines 113 extend in the shorter-side direction and are formed at a distance from each other in the longitudinal direction.

One pixel electrode 116 is arranged in a region surrounded by gate line 111 and data line 113.

Gate line 111 is led out of thin film transistor 115, and extends from pixel array region 107 to surrounding region 105. Thus, a gate pad 112 is formed in gate line 111, in surrounding region 105.

Data line 113 is led out of thin film transistor 115, and extends from pixel array region 107 to surrounding region 105. Thus, a source pad 114 is formed in data line 113, in surrounding region 105.

FIG. 7 is a cross-portional view of liquid crystal display panel 101 in display region 103. As shown in FIG. 7, an opposed substrate 120 is provided with a transparent substrate 123 such as a glass substrate, a color filter 121 formed on a main surface of transparent substrate 123 opposed to active matrix substrate 130, and an opposed electrode 122 arranged on a side closer to active matrix substrate 130 than color filter 121.

Thus, opposed electrode 122 and pixel electrode 116 are opposed to each other across a liquid crystal layer 124. Active matrix substrate 130 is provided with a transparent substrate 131 such as a glass substrate, and thin film transistor 115 formed on transparent substrate 131.

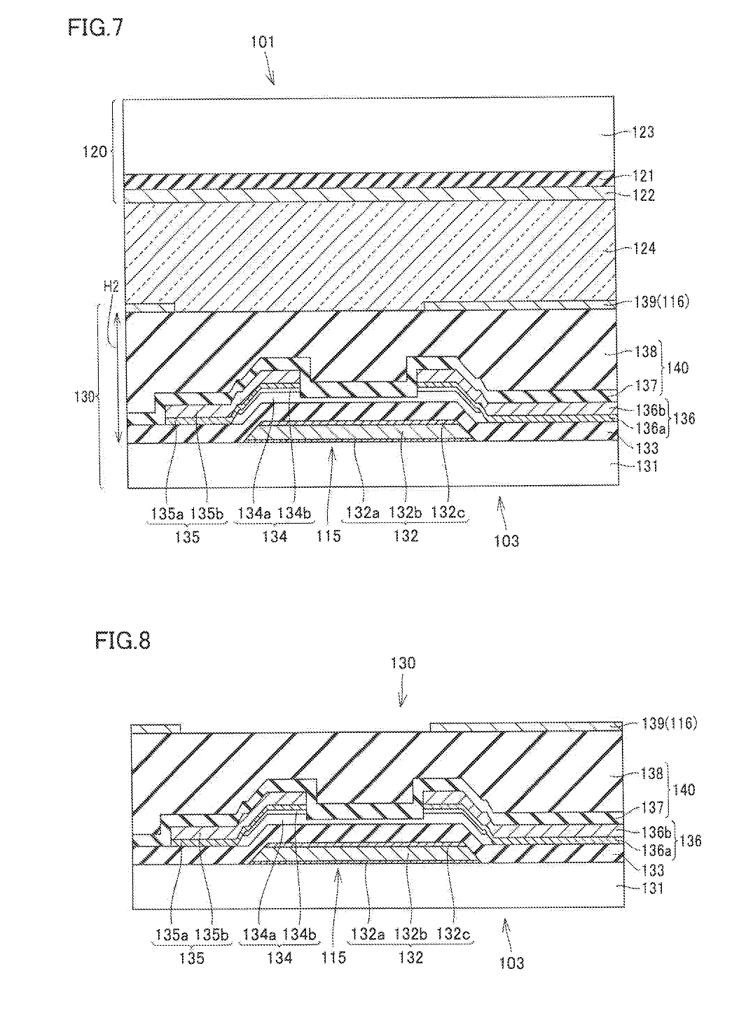

FIG. 8 is a cross-portional view of active matrix substrate 130 to show a detail of thin film transistor 115. In transparent substrate 131, thin film transistor 115 is provided with a gate electrode 132 formed on a main surface of transparent substrate 131 which is opposed to opposed substrate 120, a gate insulation film 133 formed on the main surface of transparent substrate 131 so as to cover gate electrode 132, a semiconductor layer 134 positioned on gate insulation film 133 and positioned above gate electrode 132, and a source electrode 135 and a drain electrode 136 formed on an upper surface of gate insulation film 133 so as to cover a part of semiconductor layer 134, and formed at a distance from each other.

Thus, an interlayer insulation film 140 (passivation film and planarization film) is formed so as to cover thin film transistor 115, and an ITO film 139 (pixel electrode 116) is formed on interlayer insulation film 140. Pixel electrode 116 is electrically connected to drain electrode 136. More specifically, a contact hole (not shown) is formed in interlayer insulation film 140, and pixel electrode 116 extends along an inner periphery surface of this contact hole, and pixel electrode 116 is connected to drain electrode 136.

Gate electrode 132 includes a metal film 132a formed on the main surface of transparent substrate 131, a metal film 132b formed on metal film 132a, and a metal film 132c formed on metal film 132b. Metal film 132a and metal film 132c are formed of a metal material such as Ti, and metal film 132b is formed of a metal material such as Al.

Gate insulation film 133 is formed of a material such as silicon nitride (SiNx: x is a positive number).

Semiconductor layer 134 includes an amorphous silicon film (A—Si film: i layer) 134a serving as a channel portion of thin film transistor 115, and an amorphous silicon film (n+ layer) 134b positioned on amorphous silicon film 134a and connected to the source and drain electrodes.

Source electrode 135 includes a metal film 135a formed of a material such as titanium, and a metal film 135b positioned on metal film 135a, and formed of a material such as aluminum. Drain electrode 136 also includes a metal film 136a formed of a material such as titanium, and a metal film 136b formed on metal film 136a, and formed of a material such as aluminum.

Interlayer insulation film 140 includes a passivation film 137, and a planarization film 138 formed on passivation film 137. Passivation film 137 includes a silicon nitride film and formed by CVD method at 250° C. Note that, while passivation film 137 and gate insulation film 133 include the silicon nitride film, a composition of gate insulation film 133 is denser than that of passivation film 137.

Planarization film 138 is formed of an organic material such as an acryl-based synthetic resin. That is, planarization film 138 is an organic insulation film, and passivation film 137 formed under planarization film 138 is an inorganic insulation film.

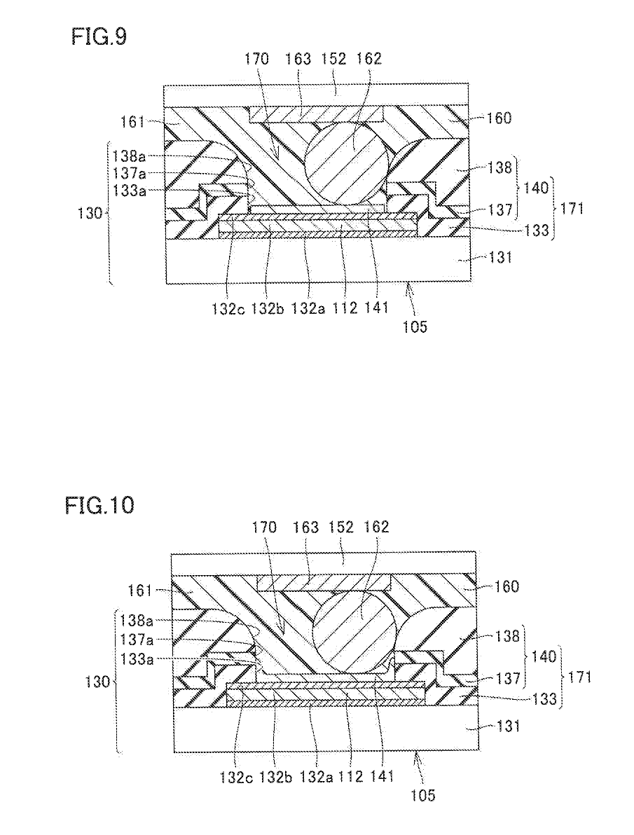

FIG. 9 is a cross-portional view of gate pad 112 formed in surrounding region 105. As shown in FIG. 9, active matrix substrate 130 has gate pad 112 formed in surrounding region 105, and an insulation layer 171 formed so as to cover gate pad 112 and having a contact hole 170.

Insulation layer 171 includes planarization film 138 serving as a first insulation film positioned as an uppermost layer of active matrix substrate 130 and passivation film 137 and gate insulation film 133 positioned under planarization film 138 and serving as a second insulation film. Contact hole 170 is formed so as to penetrate insulation layer 171, and reach an upper surface of gate pad 112.

Gate insulation film 133 is formed so as to cover a part of gate pad 112, and an outer periphery edge portion of gate pad 112 is covered with gate insulation film 133. Therefore, metal film 132b formed of aluminum is prevented from coming into contact with an ITO film (conductive film) 141, and metal film 132b is prevented from being corroded. Interlayer insulation film 140 is formed on gate insulation film 133. Interlayer insulation film 140 includes passivation film 137, and planarization film 138 formed on passivation film 137.

Contact hole 170 includes a hole portion 138a formed in planarization film 138, a hole portion 137a formed in passivation film 137, and a hole portion 133a formed in gate insulation film 133.

ITO film 141 is formed on the upper surface of gate pad 112 positioned in contact hole 170, and ITO film 141 is formed so as to be spaced from an inner periphery surface of contact hole 170.

A distance between an outer periphery edge portion of ITO film 141 and the inner periphery surface of contact hole 170 is set to about 3 μm. That is, according to the example shown in FIG. 9, ITO film 141 is only formed on the upper surface of ITO film 141.

FIG. 10 is a cross-portional view showing a variation of ITO film 141 shown in FIG. 9. According to the example shown in FIG. 10, ITO film 141 is formed on the upper surface of gate pad 112, on an inner periphery surface of hole portion 133a, and an inner periphery surface of hole portion 137a. In addition, ITO film 141 is spaced from an inner periphery surface of hole portion 138a in planarization film (first insulation film) 138.

In each example in FIGS. 9 and 10, ITO film 141 is formed so as to be spaced from the inner periphery surface of hole portion 138a in planarization film (first insulation film) 138 positioned uppermost.

Planarization film 138 is positioned as the outermost layer of active matrix substrate 130. Therefore, when gate driver 152 is mounted to gate pad 112 of active matrix substrate 130, planarization film 138 could come into contact with gate driver 152 and planarization film 138 could drop off.

Even in a case where planarization film 138 positioned as the outermost layer of active matrix substrate 130 drops off, ITO film 141 can be prevented from being attached to a piece of dropped planarization film 138.

Since ITO film 141 can be prevented from being attached to the piece of dropped planarization film 138, a defect such as short circuit can be prevented from being generated even when the piece of dropped planarization film 138 is attached to active matrix substrate 130 again.

Planarization film 138 is formed of the organic material, and passivation film 137 positioned under planarization film 138 and being in contact with planarization film 138 is formed of the inorganic material. Each of passivation film 137, and gate insulation film 133 positioned under passivation film 137 is formed of the inorganic material.

Bonding force between planarization film 138 and passivation film 137 is smaller than bonding force between gate insulation film 133 and passivation film 137, so that planarization film 138 is likely to be removed from passivation film 137.

Since ITO film 141 is formed so as to be spaced from planarization film 138, ITO film 141 can be prevented from being attached to removed planarization film 138 even when a part of planarization film 138 is removed. Therefore, even when the removed piece is attached to active matrix substrate 130 again after planarization film 138 has been removed, the defect such as short circuit can be prevented from being generated.

Gate driver 152 is arranged above gate pad 112 of active matrix substrate 130, and an anisotropic conductive film 160 is arranged between active matrix substrate 130 and gate driver 152.

A connection terminal 163 is formed on a main surface of gate driver 152 which is opposed to active matrix substrate 130.

Anisotropic conductive film 160 includes a binder 161, and a plurality of conductive particles 162 arranged in binder 161.

Conductive particles 162 are positioned between connection terminal 163 and ITO film 141, and connection terminal 163 and ITO film 141 are electrically connected by conductive particles 162.

ITO film 141 is formed on the upper surface of gate pad 112, and gate pad 112 and connection terminal 163 are connected through ITO film 141, so that a temporal contact resistance variation can be prevented.

According to the example shown in FIG. 9, even when passivation film 137 and planarization film 138 are removed, and gate insulation film 133 and interlayer insulation film 140 are removed, ITO film 141 can be prevented from being attached to the removed piece because ITO film 141 is only formed on the upper surface of gate pad 112.

According to the example shown in FIG. 10, since ITO film 141 is formed so as to reach the inner periphery surfaces of hole portion 133a and hole portion 137a, a contact area between conductive particles 162 and ITO film 141 can be largely ensured.

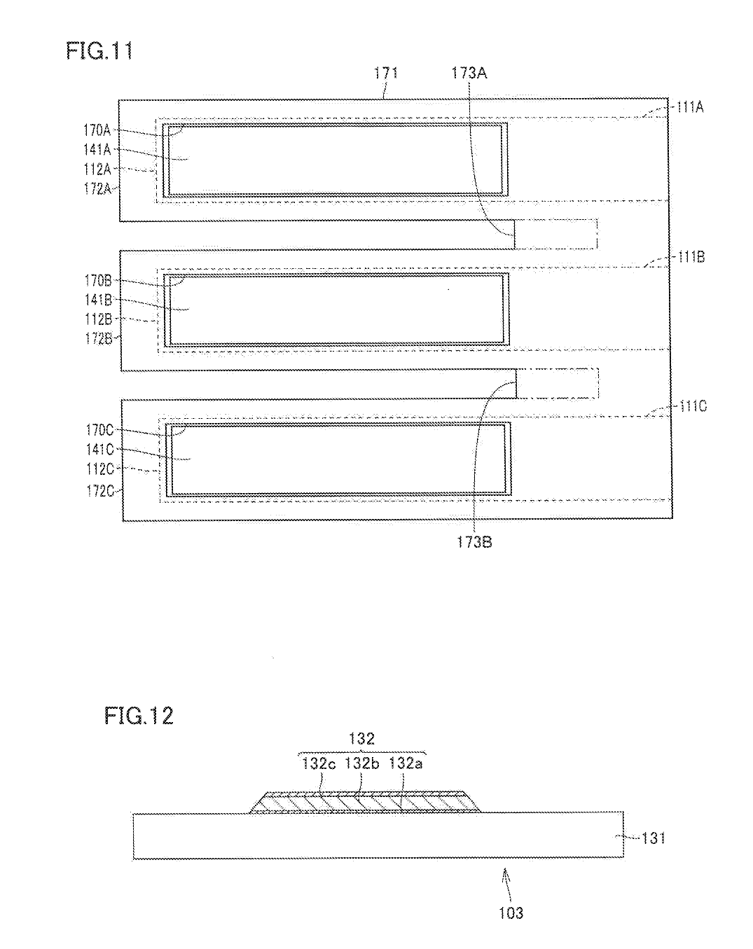

FIG. 11 is a plan view showing gate pads 112 formed in surrounding region 105. As shown in FIG. 11, gate lines 111A, 111B, and 111C are arranged at a distance from each other in one direction. In a part shown in FIG. 11, gate line (first lead wire) 111A, gate line (second lead wire) 111B, gate line (third lead wire) 111C are formed at a distance from each other in one direction.

A gate pad 112A is formed at an end of gate line 111A, and a gate pad 112B is formed at an end of gate line 111B. A gate pad 112C is formed at an end of gate line 111C.

Insulation layer 171 includes a pad covering portion 172A which covers gate pad 112A, a covering portion 172B which covers gate pad 112B, and a pad covering portion 172C which covers gate pad 112C.

A contact hole 170A which reaches gate pad 112A is formed in pad covering portion 172A, a contact hole 170B which reaches gate pad 112C is formed in pad covering portion 172B, and a contact hole 170C which reaches gate pad 112C is formed in pad covering portion 172C.

An ITO film 141A is formed on an upper surface of gate pad 112A positioned in a bottom portion of contact hole 170A, and an ITO film 141B is formed on an upper surface of gate pad 112B positioned in a bottom portion of contact hole 170B. An ITO film 141C is formed on an upper surface of gate pad 112C positioned in a bottom portion of contact hole 170C.

Pad covering portion 172A, 172B, and 172C are formed so as to cover outer periphery edge portions of gate pads 112A, 112B, and 112C, respectively.

Pad covering portion 172A and pad covering portion 172B are formed at a distance from each other, and pad covering portion 172B and pad covering portion 172C are formed at a distance from each other.

Since a gap is formed between pad covering portions, a formation region of insulation layer 171 can be small. As shown in FIG. 9, insulation layer 171 includes planarization film 138 formed of the resin material. Planarization film 138 is likely to expand when it contains water, so that when the formation region of insulation layer 171 including planarization film 138 is small, planarization film 138 can be prevented from being removed.

Pad covering portion 172A and pad covering portion 172B are formed at a distance from each other, so that even when pad covering portion 172A is removed, pad covering portion 172B can be prevented from being also removed.

Pad covering portion 172A and pad covering portion 172B are connected to each other at a connection portion 173A, and pad covering portion 172B and pad covering portion 172C are connected to each other at a connection portion 173B.

According to the example shown in FIG. 11, connection portions 173A and 173B, and edge portions of the opening edge portions of contact holes 170A, 170B, and 170C positioned on the side of display region 103 are aligned in one direction.

Note that the positions of connection portions 173A and connection portion 173B are not limited to the above position. For example, as shown by chain lines in FIG. 11, connection portions 173A and connection portions 173B may be arranged on the side closer to display region 103 than contact holes 170A, 170B, and 170C.

In a process for manufacturing active matrix substrate 130, the ITO film is likely to be left on connection portions 173A and 173B.

Thus, when connection portions 173A and 173B are arranged on the side closer to display region 103 than contact holes 170A, 170B, and 170C, ITO films 141A, 141B, and 141 C are prevented from being connected to each other through the ITO film left on connection portions 173A and 173B.

A description will be made of a method for manufacturing active matrix substrate 130 according to the first embodiment with reference to FIGS. 12 to 21.

FIG. 12 is a cross-portional view showing a first manufacturing step among steps for manufacturing active matrix substrate 130, and a cross-portional view in display region 103. FIG. 13 is a cross-portional view showing the first manufacturing steps among the steps for manufacturing active matrix substrate 130, and a cross-portional view in surrounding region 105.

With reference to FIGS. 12 and 13, a metal film formed of Ti or the like, a metal film formed of metal material such as Al, and a metal film formed of Ti or the like are sequentially formed on a main surface of a transparent substrate 131 by sputter deposition. The laminated metal films are formed to be 3000 Å in thickness. Then, the laminated metal films are patterned with a mask, so that gate electrode 132 is formed in a region serving as pixel array region 107, gate pad 112 is formed in a region serving as surrounding region 105, and gate line 111 is formed to connect gate electrode 132 and gate pad 112.

FIG. 14 shows a manufacturing step after the manufacturing step shown in FIGS. 12 and 13, and is a cross-portional view in display region 103, and FIG. 15 is a cross-portional view in surrounding region 105 in the manufacturing step shown in FIG. 14.

As shown in FIGS. 14 and 15, gate insulation film 133 is formed on transparent substrate 131 so as to cover gate electrode 132 and gate pad 112. Gate insulation film 133 is formed by CVD method at 330° C. to be 3500 Å in thickness.

After gate insulation film 133 has been formed, an amorphous silicon film (i layer) and an amorphous silicon film (n+ layer) are sequentially formed on an upper surface of gate insulation film 133 by CVD method.

The amorphous silicon film (i layer) and the amorphous silicon film (n+ layer) are formed to be about 1000 Å and about 400 Å in thickness, respectively, and patterned into a desired shape, whereby semiconductor layer 134 is formed. Semiconductor layer 134 is formed on gate insulation film 133 and above gate electrode 132 formed in display region 103.

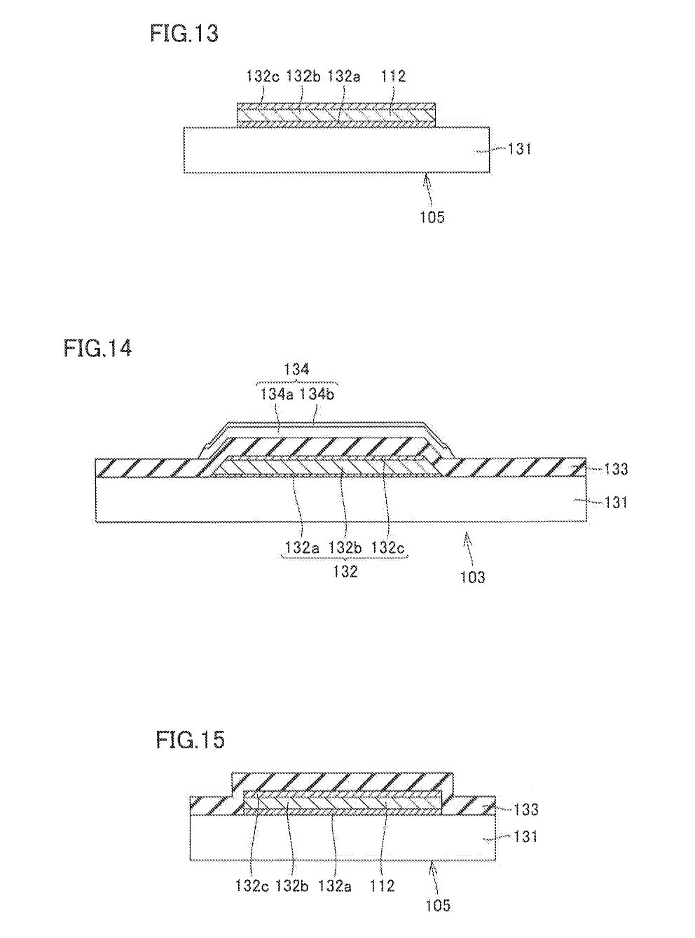

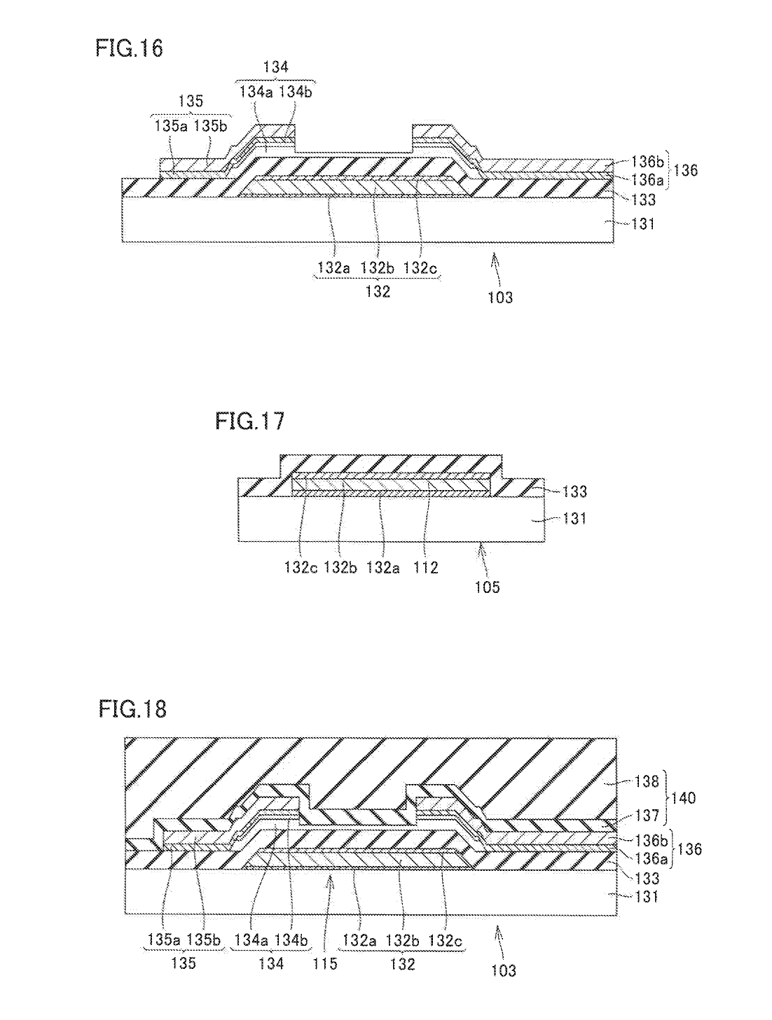

FIG. 16 shows a manufacturing step after the manufacturing step shown in FIGS. 14 and 15, and is a cross-portional view in display region 103. FIG. 17 is a cross-portional view in surrounding region 105 in the manufacturing step shown in FIG. 16.

With reference to FIGS. 16 and 17, a metal film formed of titanium, a metal film formed of aluminum are formed on gate insulation film 133 so as to cover semiconductor layer 134 by sputtering.

After the two metal films have been formed, the metal films are patterned, whereby source electrode 135 and drain electrode 136 are formed. Source electrode 135 and drain electrode 136 are formed at a distance from each other.

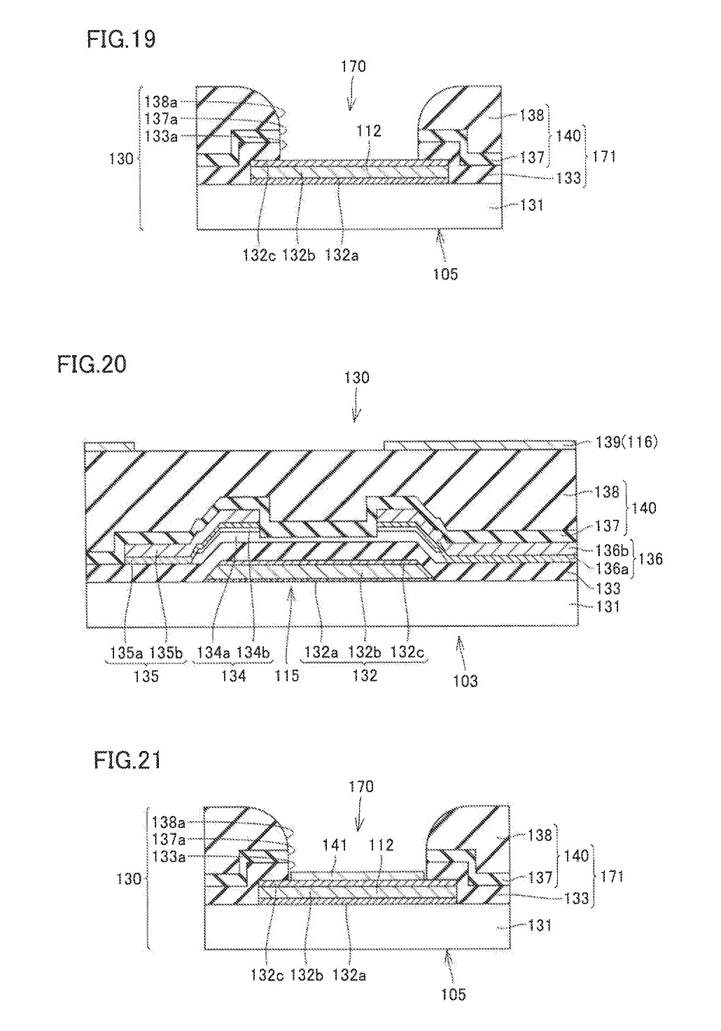

FIG. 18 shows a manufacturing step after the manufacturing step shown in FIGS. 16 and 17, and is a cross-portional view in display region 103, and FIG. 19 is a cross-portional view in surrounding region 105 in the manufacturing step shown in FIG. 18.

With reference to FIGS. 18 and 19, a silicon nitride film and an acrylic-based synthetic resin are formed on gate insulation film 133 so as to cover source electrode 135 and drain electrode 136, whereby passivation film 137 and planarization film 138 serving as the outermost insulation film are formed. Thus, interlayer insulation film 140 is formed.

Planarization film 138 is patterned with a mask, and passivation film 137 and gate insulation film 133 are patterned using patterned planarization film 138 as a mask. Thus, contact hole 170 is formed so as to penetrate insulation layer 171 and reach gate pad 112.

FIG. 20 shows a manufacturing step after the manufacturing step shown in FIGS. 18 and 19, and is a cross-portional view in display region 103, and FIG. 21 is a cross-portional view in surrounding region 105 in the manufacturing step shown in FIG. 20.

As shown in FIGS. 20 and 21, an ITO film is formed on planarization film 138 and gate pad 112, and the ITO film is patterned, whereby pixel electrode 116 is formed and ITO film 141 is formed on gate pad 112. ITO film 141 formed on gate pad 112 is formed so as to be spaced from at least a part defined by planarization film 138 in the inner periphery surface of contact hole 170. Note that, according to the example shown in FIG. 21, ITO film 141 is formed so as to be spaced from the inner periphery surface of contact hole 170. Thus, active matrix substrate 130 according to this embodiment can be manufactured.

### Second Embodiment

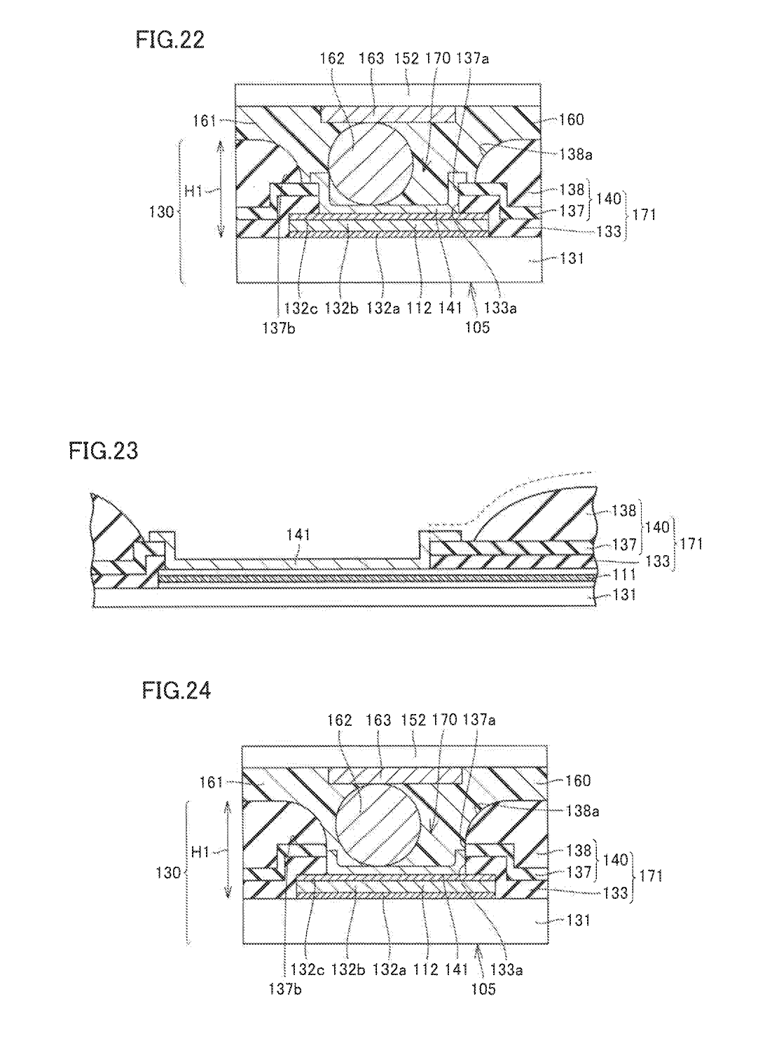

A description will be made of liquid crystal display panel 101 according to a second embodiment of the present invention with reference to FIGS. 22 to 28 and 7. Note that, among components shown in FIGS. 22 to 28, as for the component which has the same or corresponding configuration as that of the component shown in FIGS. 1 to 21, the same reference is allocated and a description thereof is omitted occasionally.

FIG. 22 is a cross-portional view of liquid crystal display panel 101 in surrounding region 105 according to the second embodiment of the present invention. As shown in FIG. 22, an opening area of hole portion 138a of planarization film 138 is larger than an opening area of hole portion 133a of gate insulation film 133.

An opening edge portion of hole portion 138a of planarization film 138 is spaced from an opening edge portion of hole portion 137a of passivation film 137, a part of an upper surface 137b of passivation film 137 is exposed from planarization film 138. When planarization film 138 and passivation film 137 are planarly-viewed from an extending direction of contact hole 170, hole portion 137a is positioned in hole portion 138a, and a part of upper surface 137b of passivation film 137 is positioned in hole portion 138a.

ITO film 141 is formed so as to reach upper surface 137b of passivation film 137 positioned in hole portion 138a. ITO film 141 is formed so as to reach upper surface 137b of passivation film 137 from the upper surface of gate pad 112 through inner periphery surfaces of hole portion 133a and hole portion 137a, and formed so as to be spaced from an inner periphery surface of hole portion 138a.

Since ITO film 141 is formed so as to cover not only the upper surface of gate pad 112, but also the inner periphery surfaces of hole portions 133a and 137a and a part of the upper surface of passivation film 137, a large contact region can be ensured between ITO film 141 and conductive particles 162. Thus, connection between gate driver 152 and gate pad 112 can be ensured.

According to the example shown in FIG. 22 also, even when planarization film 138 is removed, ITO film 141 can be prevented from being attached to the removed piece because ITO film 141 is formed so as to be spaced from planarization film 138.

A total film thickness H1 of gate insulation film 133, planarization film 138, and passivation film 137 positioned in surrounding region 105 is set to about 1.5 μm to 1 μm.

As shown in FIG. 7, a total film thickness H2 of gate insulation film 133, planarization film 138, and passivation film 137 positioned in display region 103 is set to about 2.5 μm to 3 μm.

Film thicknesses of gate insulation film 133 and passivation film 137 are roughly constant from display region 103 to surrounding region 105. A film thickness of planarization film 138 positioned in surrounding region 105 is formed so as to be thinner than a film thickness of planarization film 138 positioned in display region 103. At least film thickness of planarization film 138 of a part for defining contact hole 170 and a part positioned around contact hole 170 is thinner than the film thickness of planarization film 138 positioned in display region 103.

Therefore, a height of insulation layer 171 for defining contact hole 170 can be low, so that gate driver 152 and ITO film 141 can be close to each other. Thus, conductive particle 162 having a small diameter can be used. Since conductive particle 162 having the small diameter can be used, conductive particles 162 can be aligned on ITO film 141. Thus, conductivity between gate driver 152 and gate pad 112 can be improved.

FIG. 23 is a cross-portional view showing gate pad 112 and its vicinity, and the cross-portional view is taken along a longitudinal direction of gate pad 112.

As shown in FIG. 23, planarization film 138 is formed so as to be spaced from the opening portion of passivation film 137, and a part of the upper surface of passivation film 137 is exposed from planarization film 138. Thus, ITO film 141 is formed so as to reach the exposed upper surface of passivation film 137 from the upper surface of gate pad 112, and be spaced from planarization film 138.

Note that, according to the example shown in FIGS. 22 and 23, planarization film 138 is formed so as to be spaced from the opening portion of hole portion 137a of passivation film 137, but as shown in FIG. 24, planarization film 138 may be formed such that hole portion 138a of planarization film 138 coincides with hole portion 137a of passivation film 137. In this case, ITO film 141 formed on gate pad 112 is formed so as to be positioned lower than hole portion 138a of planarization film 138.

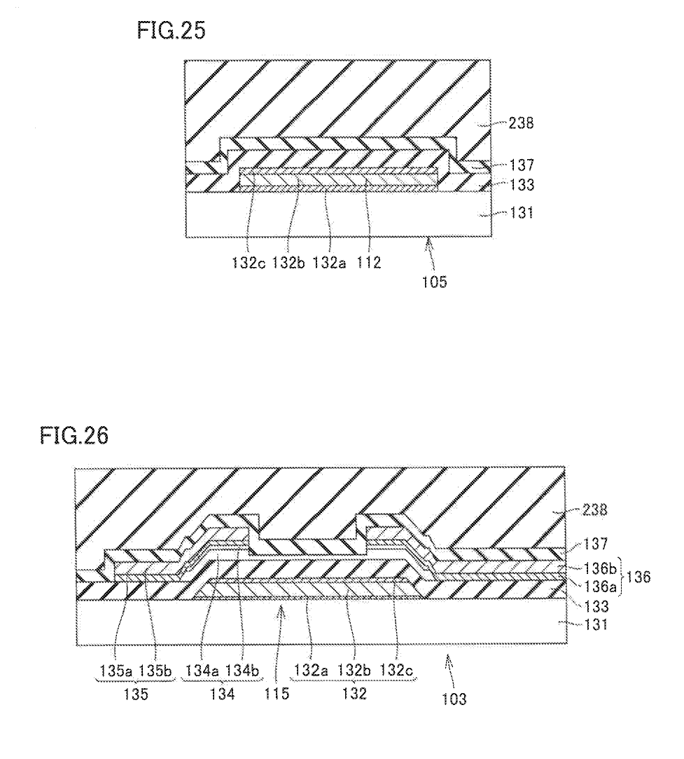

A description will be made of a method for manufacturing active matrix substrate 130 according to the second embodiment with reference to FIGS. 25 to 30.

FIG. 25 shows a state in which after gate pad 112 and gate insulation film 133 have been formed on the upper surface of transparent substrate 131, passivation film 137 and an insulation film 238 are formed, and is a cross-portional view in surrounding region 105. FIG. 26 is a cross-portional view in display region 103 in the state shown in FIG. 25. Note that insulation film 238 is an organic insulation film formed of an acryl-based synthetic resin material.

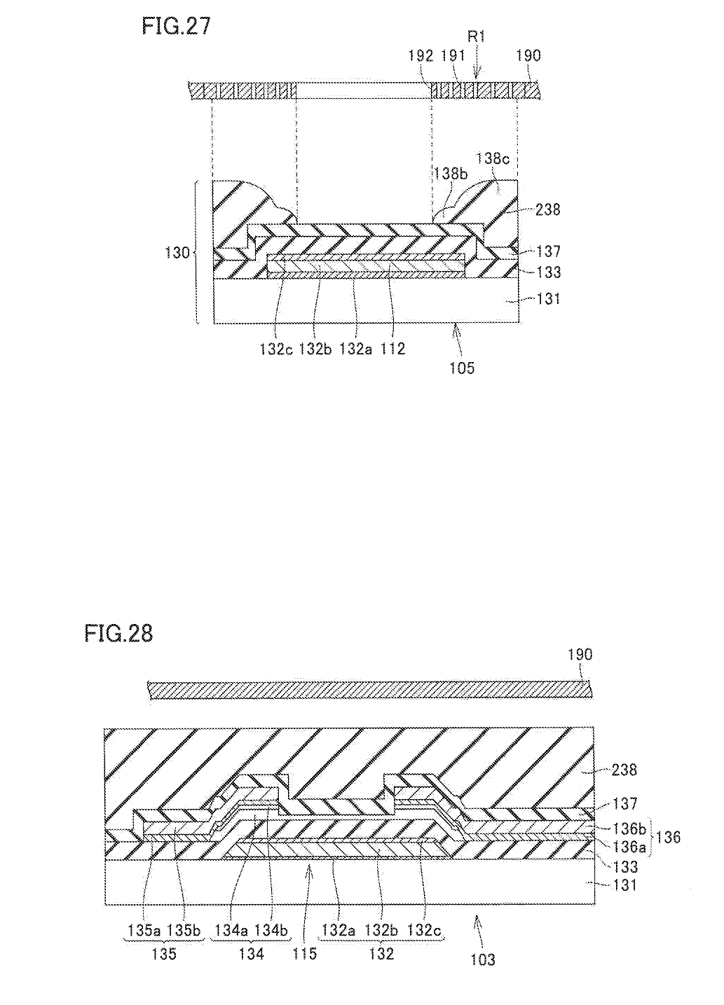

FIG. 27 shows a manufacturing step after the manufacturing step shown in FIGS. 25 and 26, and is a cross-portional view in surrounding region 105, and FIG. 28 is a cross-portional view in display region 103 in the manufacturing step shown in FIG. 27.

As shown in FIGS. 27 and 28, a mask 190 is arranged above insulation film 238.

An opening portion 192 is formed in mask 190 at a part positioned above contact hole 170 to be formed, and a plurality of slits 191 are formed in a region R1 positioned around opening portion 192, in mask 190. Note that slit 191 is not formed in mask 190 in a part positioned on the opposite side of opening portion 192 with respect to the part of region R1. Slits 191 are distributed so as to increase toward opening portion 192. After insulation film 238 has been exposed and patterned with mask 190, insulation film 238 positioned under opening portion 192 is removed, and a hole portion is formed.

A thin film portion 138b and a thick film portion 138c are formed in insulation film 238 positioned under region R1 of mask 190. Thin film portion 138b is positioned around the hole portion, and thick film portion 138c becomes thick with distance from thin film portion 138b. As shown in FIG. 28, since insulation film 238 formed in display region 103 is shielded by mask 190, its thickness before the exposure step is left unchanged. Therefore, a thickness of thick film portion 138c is smaller than the thickness of insulation film 238 left in display region 103.

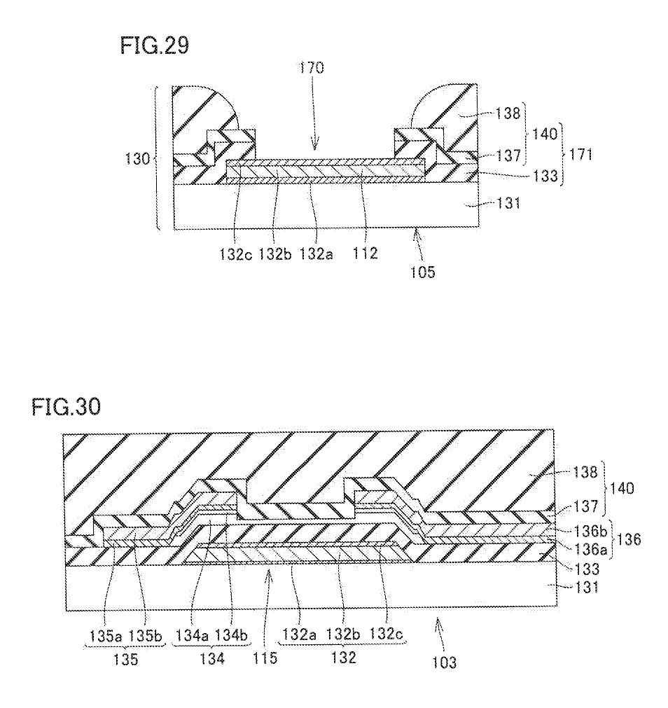

FIG. 29 shows a manufacturing step after the manufacturing step shown in FIGS. 27 and 28, and is a cross-portional view in surrounding region 105. FIG. 30 is a cross-portional view in display region 103 in the manufacturing step in FIG. 29.

With reference to FIGS. 29 and 30, passivation film 137 and gate insulation film 133 are treated by dry etching using insulation film 238 shown in FIGS. 27 and 28 as a mask.

Thus, contact hole 170 is formed so as to reach gate pad 112. At this time, thin film portion 138b shown in FIG. 27 is removed by the dry etching, and a part of the upper surface of passivation film 137 is exposed.

Thus, the film thickness of planarization film 138 positioned around contact hole 170 can be smaller than the film thickness of planarization film 138 positioned in display region 103.

### Third Embodiment

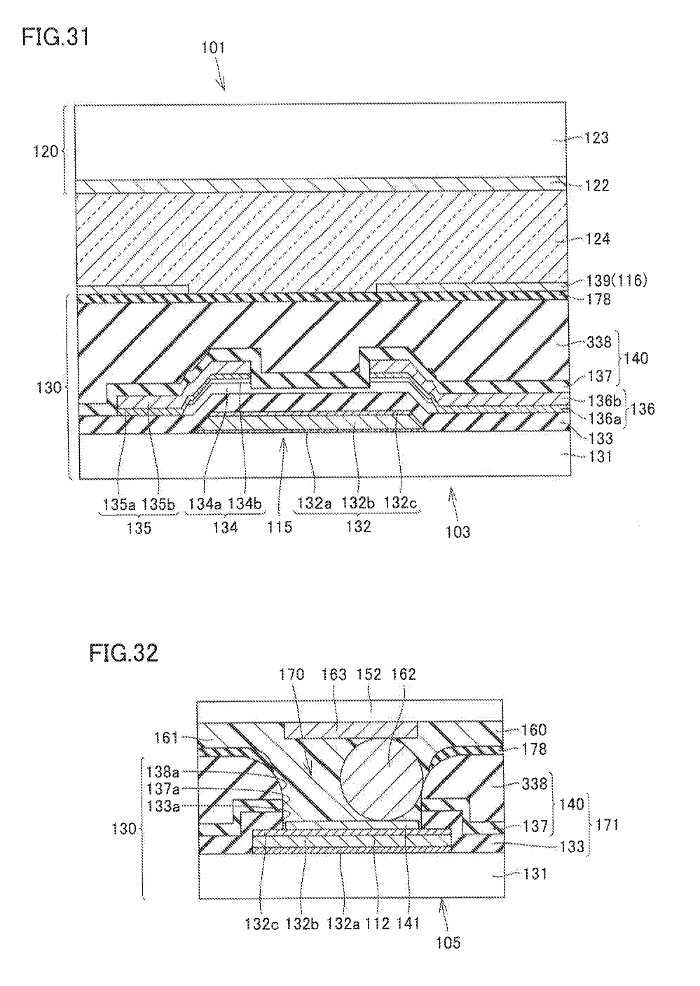

A description will be made of liquid crystal display panel 101 according to a third embodiment of the present invention with reference to FIGS. 31 to 38. In addition, among components shown in FIGS. 31 to 38, as for the component which has the same or corresponding configuration as that of the component shown FIGS. 1 to 30, the same reference is allocated and a description thereof is omitted occasionally.

FIG. 31 is a cross-portional view of liquid crystal display panel 101 in display region 103 according to the third embodiment of the present invention. FIG. 32 is a cross-portional view of liquid crystal display panel 101 in surrounding region 105 according to the third embodiment of the present invention.

According to the example shown in FIGS. 31 and 32, a color layer 338 of a colored transparent insulation film is formed in active matrix substrate 130 to function as a color filter. Color layer 338 is formed of an organic material such as an acryl-based synthetic resin, and formed on an upper surface of passivation film 137. A protective film 178 formed of an inorganic material is formed on an upper surface of color layer 338. Pixel electrode 116 is formed on an upper surface of protective film 178 in display region 103. Note that a height of color layer 338 formed in surrounding region 105 may be lower than a height of color layer 338 formed in display region 103.

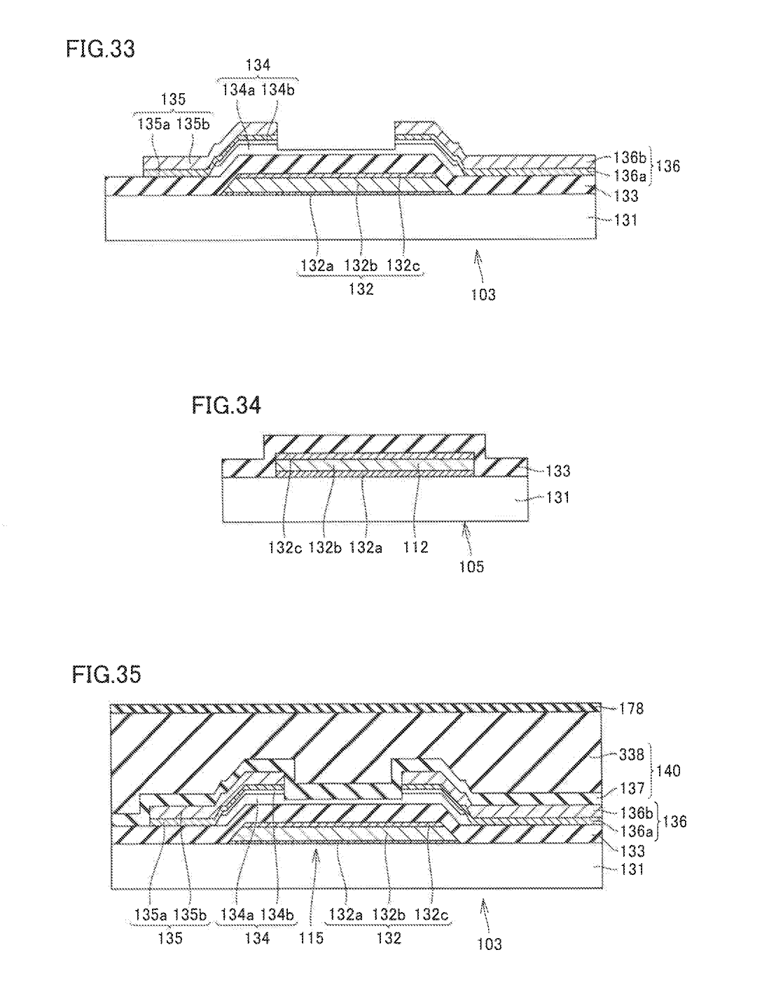

A description will be made of a method for manufacturing liquid crystal display panel 101 according to the third embodiment of the present invention with reference to FIGS. 33 to 38.

FIG. 33 shows a state in which gate electrode 132, gate insulation film 133, semiconductor layer 134, source electrode 135, and drain electrode 136 have been formed on transparent substrate 131 in a process for manufacturing active matrix substrate 130, and is a cross-portional view in display region 103. FIG. 34 is a cross-portional view in surrounding region 105 in the state shown in FIG. 33.

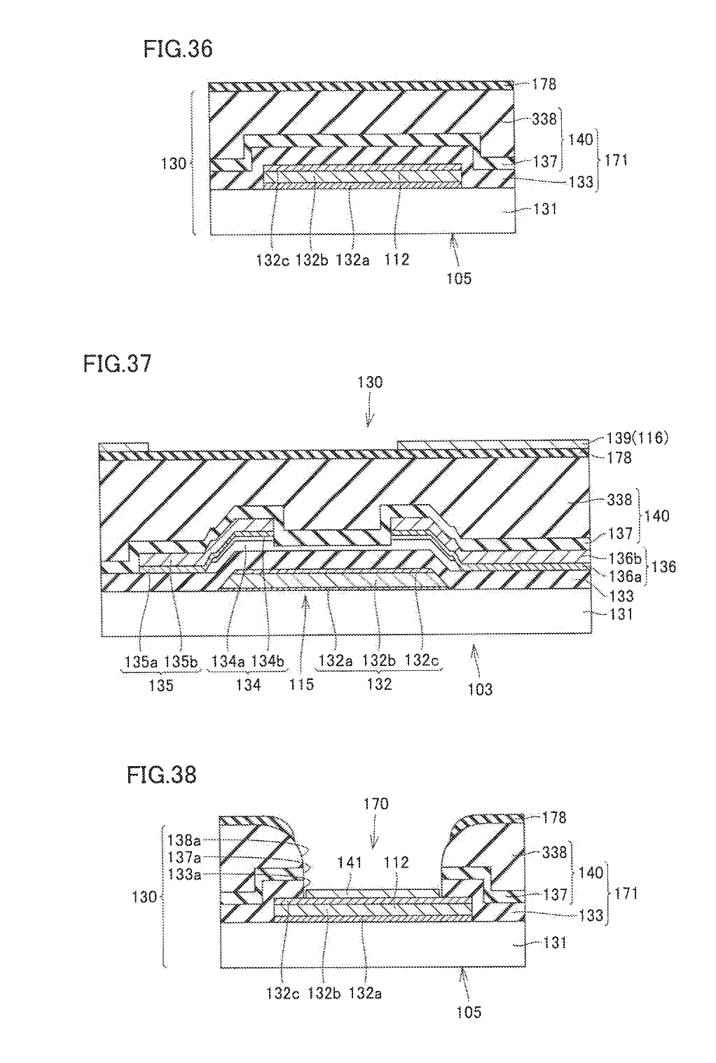

FIG. 35 shows a manufacturing step after the manufacturing step shown in FIGS. 33 and 34, and is a cross-portional view in display region 103. FIG. 36 is a cross- portional view in surrounding region 105 in the manufacturing step shown in FIG. 35. As shown in FIGS. 35 and 36, passivation film 137, color layer 338, and protective film 178 are sequentially formed. Protective film 178 is formed so as to cover a whole surface of color layer 338.

FIG. 37 shows a manufacturing step after the manufacturing step shown in FIGS. 35 and 36, and is a cross-portional view in display region 103. FIG. 38 is a cross-portional view in surrounding region 105 in the manufacturing step shown in FIG. 37.

With reference to FIGS. 37 and 38, color layer 338 and protective film 178 are patterned. Thus, passivation film 137 and gate insulation film 133 are treated by dry etching using patterned protective film 178 and color layer 338 as a mask. Thus, contact hole 170 is formed.

Since the upper surface of color layer 338 is covered with protective film 178 when passivation film 137 and gate insulation film 133 are treated by the dry etching, color layer 338 can be prevented from being damaged.

After contact hole 170 has been formed, pixel electrode 116 is formed on the upper surface of color layer 338 positioned in display region 103, and ITO film 141 is formed on an upper surface of gate pad 112. Thus, active matrix substrate 130 according to the third embodiment of the present invention can be manufactured.

### Fourth Embodiment

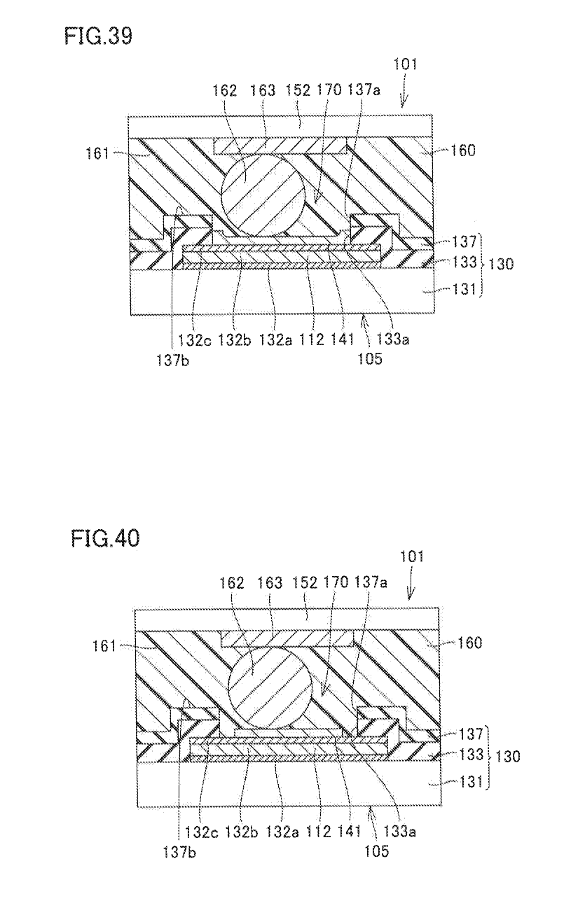

A description will be made of liquid crystal display panel 101 according to a fourth embodiment of the present invention with reference to FIGS. 39 and 7. Note that, among components shown in FIG. 39, as for the component which has the same or corresponding configuration as that of the component shown FIGS. 1 to 38, the same reference is allocated and a description thereof is omitted occasionally. FIG. 39 is a cross-portional view of liquid crystal display panel 101 in surrounding region 105 according to the fourth embodiment of the present invention.

While planarization film 138 is formed in display region 103 in active matrix substrate 130, as shown in FIG. 7, planarization film 138 is not formed in surrounding region 105 as shown in FIG. 39.

Therefore, passivation film 137 is positioned as an outermost layer of active matrix substrate 130 in surrounding region 105.

Contact hole 170 includes hole portion 137a of passivation film 137, and hole portion 133a of gate insulation film 133. According to the example shown in FIG. 39, ITO film 141 is formed on an upper surface of gate pad 112, and formed so as to reach an inner periphery surface of hole portion 133a. ITO film 141 is formed so as to be spaced from an inner periphery surface of hole portion 137a.

Therefore, even when passivation film 137 is removed in bonding gate driver 152, ITO film 141 can be prevented from being attached on a piece of removed passivation film 137, so that a defect such as short circuit can be prevented from being generated.

In addition, as shown in FIG. 40, ITO film may be formed only on the upper surface of gate pad 112.

### Fifth Embodiment

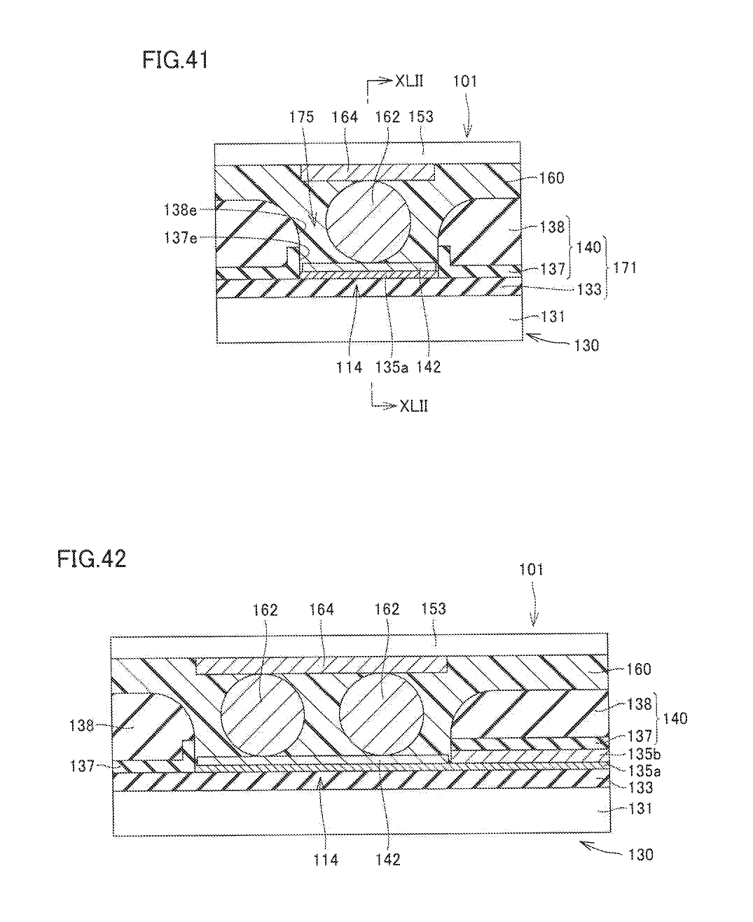

A description will be made of liquid crystal display panel 101 according to a fifth embodiment of the present invention with reference to FIGS. 41 to 48. Note that, among components shown in FIGS. 41 to 48, as for the component which has the same or corresponding configuration as that of the component shown FIGS. 1 to 40, the same reference is allocated and a description thereof is omitted occasionally.

FIG. 41 is a cross-portional view of source pad 114 of liquid crystal display panel 101 and a part positioned around source pad 114 according to the fifth embodiment of the present invention. As shown in FIG. 41, liquid crystal display panel 101 includes active matrix substrate 130, source driver 153 connected to source pad 114 formed on active matrix substrate 130, and anisotropic conductive film 160 arranged between source driver 153 and active matrix substrate 130.

Active matrix substrate 130 includes transparent substrate 131, gate insulation film 133 formed on an upper surface of transparent substrate 131, source pad 114 formed on an upper surface of gate insulation film 133, and interlayer insulation film 140 formed around source pad 114.

Source pad 114 serves as metal film 135a positioned at an end of data line 113. An ITO film 142 is formed on an upper surface of metal film 135a. Metal film 135a is formed of titanium. Metal film 135a is exposed from metal film 135b as source pad 114, and ITO film 142 is formed on the exposed upper surface of metal film 135a. Metal film 135a is formed on gate insulation film 133.

Insulation layer 171 is formed around metal film 135a, and insulation layer 171 includes gate insulation film 133, passivation film 137, and planarization film 138 formed on passivation film 137. A contact hole 175 is formed in insulation layer 171 so as to reach source pad 114.

Note that, according to the example shown in FIG. 41, planarization film 138 is positioned as an outermost layer (upper layer) of active matrix substrate 130. Contact hole 175 is defined by a hole portion 138e formed in planarization film 138, and a hole portion 137e formed in passivation film 137. ITO film 142 and source pad 114 (metal film 135a) are positioned in a bottom portion of contact hole 175.

Source driver 153 is arranged above source pad 114, and a connection terminal 164 is formed on a lower surface of source driver 153. Thus, conductive particles 162 are positioned between connection terminal 164 and ITO film 142, so that source pad 114 and connection terminal 164 are electrically connected.

According to active matrix substrate 130 and liquid crystal display panel 101 configured as described above, even when planarization film 138 positioned as the outermost layer of active matrix substrate 130 is removed, ITO film 142 can be prevented from being attached to the removed piece. Therefore, even when the removed piece of the planarization film 138 is attached to active matrix substrate 130 again, a defect such as short circuit can be prevented from being generated.

FIG. 42 is a cross-portional view taken along a line XLII-XLII in FIG. 41. As shown in FIG. 42, metal film 135b formed of aluminum is formed on an upper surface of metal film 135a on the side closer to pixel array region 107 than source pad 114. That is, metal film 135b is removed in a bottom portion of contact hole 175, metal film 135a (source pad 114) is exposed from metal film 135b, and ITO film 142 is formed on the exposed upper surface of metal film 135a. ITO film 142 is formed so as to be spaced from metal film 135b.

According to the example shown in FIGS. 41 and 42, ITO film 142 is formed on source pad 114, and formed so as to be spaced from an inner periphery surface of contact hole 175. Especially, ITO film 142 is formed so as to be spaced from an inner periphery surface of hole portion 138e in the inner periphery surface of contact hole 175. In addition, ITO film 142 may be formed so as to reach an inner periphery surface of hole portion 137e formed in passivation film 137. Even in the case where ITO film 142 is formed so as to reach the inner periphery surface of hole portion 137e, ITO film 142 is formed so as to be spaced from metal film 135b.

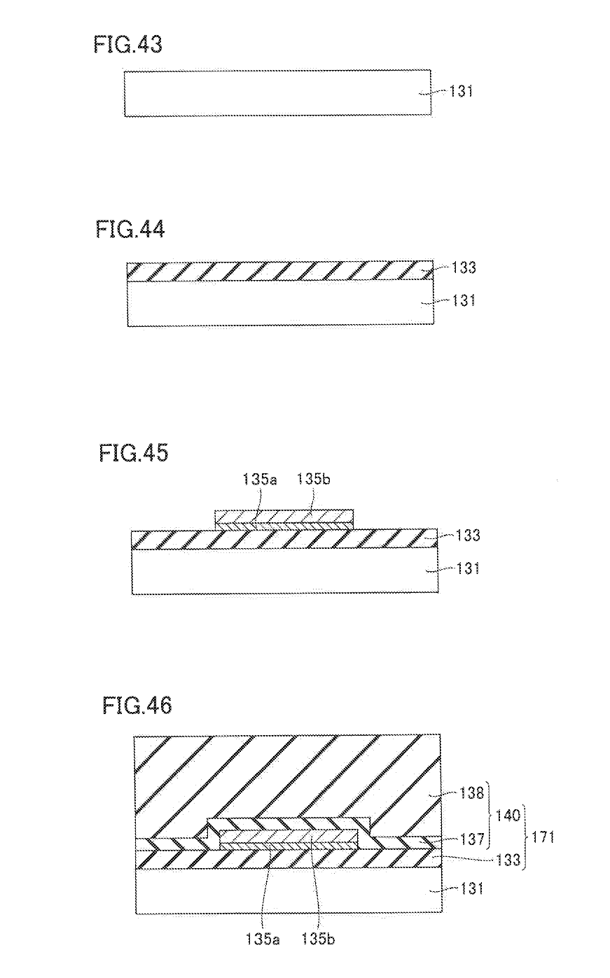

A description will be made of a method for manufacturing source pad 114 with reference to FIGS. 43 to 48. FIG. 43 is a cross-portional view of a region for forming source pad 114 in a first step for manufacturing active matrix substrate 130 shown in FIGS. 12 and 13.

With reference to FIG. 43, a metal film formed of Ti or the like, a metal film formed of a metal material such as Al, and a metal film formed of Ti or the like are sequentially formed on the main surface of transparent substrate 131. Then, the laminated metal films are patterned, and the laminated metal films in the region for forming source pad 114 are removed, in the main surface of transparent substrate 131.

FIG. 44 is a cross-portional view in the region for forming source pad 114 in the manufacturing step shown in FIGS. 14 and 15. As shown in FIG. 44, gate insulation film 133 is formed in the region for forming source pad 114, in the main surface of transparent substrate 131.

After gate insulation film 133 has been formed, an amorphous silicon film (i layer), an amorphous silicon film (n+ layer) are laminated also in the region for forming source pad 114. After the laminated amorphous silicon film (i layer) and amorphous silicon film (n+ layer) have been formed, and patterned with a mask, the amorphous silicon film (i layer) and the amorphous silicon film (n+ layer) are removed in the region for forming source pad 114.

FIG. 45 is a cross-portional view of the region for forming source pad 114, in the manufacturing step shown in FIGS. 16 and 17. With reference to FIG. 45, metal film 135a formed of titanium, and metal film 135b formed of aluminum are formed by sputtering also in the region for forming source pad 114, in the main surface of transparent substrate 131. Then, after metal film 135a and metal film 135b have been patterned, a metal laminated film including metal film 135a and metal film 135b is left in the region for forming source pad 114.

FIG. 46 is a cross-portional view of the region for forming source pad 114 in the manufacturing step shown in FIGS. 18 and 19. With reference to FIG. 46, passivation film 137 and planarization film 138 are sequentially formed so as to cover metal films 135a and 135b.

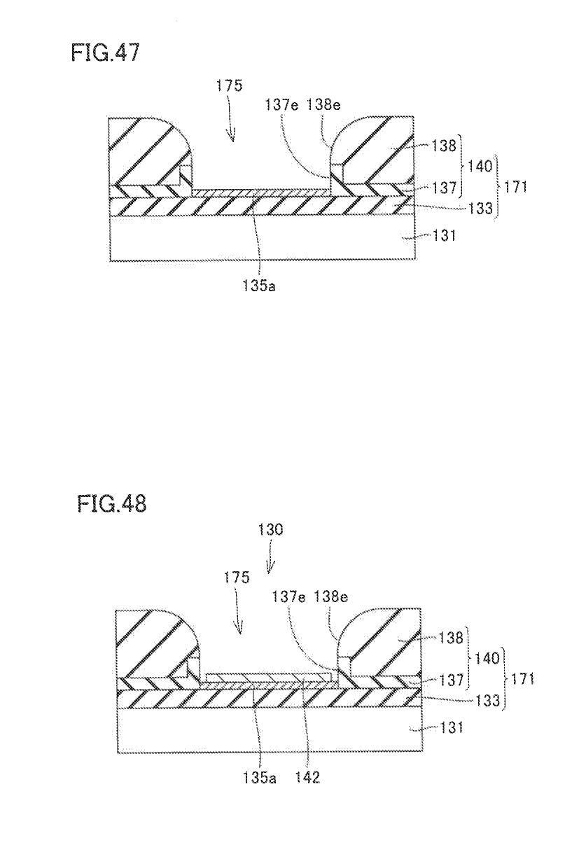

FIG. 47 shows a manufacturing step after the manufacturing step shown in FIG. 46, and is a cross-portional view of the region for forming source pad 114.

With reference to FIG. 47, planarization film 138 is patterned, and hole portion 138e is formed. Then, passivation film 137 is patterned using planarization film 138 having hole portion 138e as a mask, whereby hole portion 137e is formed in passivation film 137. Thus, contact hole 175 is formed.

Thus, metal film 135b exposed from planarization film 138 and passivation film 137 is removed due to contact hole 175. After metal film 135b formed of aluminum and positioned in the bottom portion of contact hole 175 has been removed, metal film 135a is exposed to planarization film 138 and passivation film 137 due to contact hole 175. Thus, source pad 114 is formed.

FIG. 48 shows a manufacturing step after the manufacturing step shown in FIG. 47, and is a cross-portional view of the region for forming source pad 114. As shown in FIG. 48, an ITO film is formed on an upper surface of metal film 135a (source pad 114) which was exposed from contact hole 175, whereby ITO film 142 is formed. Thus, active matrix substrate 130 provided with source pad 114 can be manufactured.

While the description has been made of the embodiments of the present invention in the above, it is to be understood that the disclosed embodiments are only illustrative and not restrictive in all respects. The scope of the present invention is interpreted by the appended claims, and it is intended that all kinds of variations are contained in a meaning and a range equivalent to the claims. Furthermore, the above numeric value is illustrative, and the present invention is not limited to the above numeric value and range.

### INDUSTRIAL APPLICABILITY

The present invention is usefully applied to an active matrix substrate, a liquid crystal display panel, a liquid crystal display device, and a method for manufacturing the active matrix substrate.

### REFERENCE SIGNS LIST

101 liquid crystal display panel,
103 display region,
104 non-display region,
105 surrounding region,
107 pixel array region,
111 gate line,
113 data line,
114 source pad,
115 thin film transistor,
116 pixel electrode,
120 opposed substrate,
121 color filter,
122 opposed electrode,
123 transparent substrate,
124 liquid crystal layer,
130 active matrix substrate,
131 transparent substrate,
132 gate electrode,
132a, 132b, 132c metal film,
133 gate insulation film,
133a, 137a, 138a, hole portion,
134 semiconductor layer,
134a amorphous silicon film,
134b amorphous silicon film (n+ layer),
135 source electrode,
136 drain electrode,
137 passivation film,
137b upper surface,
138c thick film portion,
138b thin film portion,
138 planarization film,
139 ito film,
140 interlayer insulation film,
141 ito film,
150 gate terminal portion,
151 source terminal portion,
152 gate driver,
153 source driver,
154 printed substrate wire,
155 display control circuit,
156 polarization plate,
160 anisotropic conductive film,
161 binder,
162 conductive particle,
163 connection terminal,
170 contact hole,
171 insulation layer,
172a, 172b pad covering portion,
173a, 173b connection portion,
178 protective film,
181, 182 casing,
183 opening portion,
184 operating circuit,
185 supporting member,
186 backlight unit,
190 mask,
191 slit,
192 opening portion,
200 liquid crystal display element,
238 insulation film,
200 liquid crystal display device,
338 color layer,
500 television receiver.

1. An active matrix substrate comprising:
a substrate including a pixel array region where switching elements are arranged, and a surrounding region positioned around said pixel array region;
a lead wire led out from said switching element to said surrounding region;
a pad portion formed in said lead wire, and positioned in said surrounding region;
an insulation layer formed so as to cover said pad portion, including an inorganic insulation film formed of an inorganic material, and an organic insulation film positioned on said inorganic insulation film and formed of an organic material, and having a contact hole formed so as to reach said pad portion; and
a conductive film positioned in said contact hole, and formed on said pad portion, wherein
said conductive film is formed so as to be spaced from a part defined by said organic insulation film in an inner periphery surface of said contact hole.

2. The active matrix substrate according to claim 1, wherein
said conductive film is formed so as to be spaced from the inner periphery surface of said contact hole.

3. The active matrix substrate according to claim 1, wherein
a first hole portion for defining a part of said contact hole is formed in said organic insulation film,
a second hole portion for defining a part of said contact hole is formed in said inorganic insulation film, and
said conductive film is formed so as to reach an inner periphery surface of said second hole portion from said pad portion.

4. The active matrix substrate according to claim 3, wherein
said second hole portion and an upper surface of said inorganic insulation film are positioned in said first hole portion when said organic insulation film and said inorganic insulation film are viewed from an extending direction of said contact hole, and
said conductive film is formed so as to reach the upper surface of said inorganic insulation film positioned in said first hole portion.

5. The active matrix substrate according to claim 1, wherein
said organic insulation film is formed so as to cover said switching element formed in said pixel array region, and
a thickness of said organic insulation film in the part for defining said contact hole is formed so as to be thinner than a thickness of said organic insulation film in the part positioned in said pixel array region.

6. The active matrix substrate according to claim 1, wherein
said lead wire includes a first lead wire and a second lead wire arranged at a distance from each other in one direction,
said pad portion includes a first pad portion formed in said first lead wire, and a second pad portion formed in said second lead wire,
said insulation layer includes a first covering portion for covering said first pad portion, and a second covering portion for covering said second pad portion,
a first contact hole is formed so as to reach said first pad portion in said first covering portion, and a second contact hole is formed so as to reach said second pad portion in said second covering portion, and
said first covering portion and said second covering portion are formed at a distance from each other.

7. The active matrix substrate according to claim 6, wherein
said first covering portion and said second covering portion are connected to each other on a side closer to said pixel array region than said first contact hole and said second contact hole.

8. The active matrix substrate according to claim 1, wherein
said organic insulation film serves as a color film,
said insulation layer includes a protective film formed on said organic insulation film, and
said organic insulation film and said protective film are formed on said pad portion and in said pixel array region.

9. A liquid crystal display panel comprising:
the active matrix substrate according to claim 1;
an opposed substrate arranged at a distance so as to be opposed to said active matrix substrate; and
a liquid crystal layer sealed between said opposed substrate and said active matrix substrate.

10. A liquid crystal display device comprising:
the liquid crystal display panel according to claim 9;
a first polarization plate arranged on an opposite side of said liquid crystal layer with respect to said active matrix substrate;
a second polarization plate arranged on an opposite side of said liquid crystal layer with respect to said opposed substrate; and
a backlight unit irradiating said liquid crystal display panel with light.

11. A method for manufacturing an active matrix substrate comprising the steps of:
preparing a substrate including a first region serving as a pixel array region and a second region serving as a surrounding region;
forming a gate electrode in said first region, a pad portion in said second region, and a lead wire for connecting said gate electrode and said pad portion;
forming an inorganic insulation film on said substrate;
forming a semiconductor film on said inorganic insulation film so as to be positioned above said gate electrode;
forming a first electrode on said semiconductor film;
forming a second electrode on said semiconductor film so as to be positioned at a distance from said first electrode;
forming an organic insulation film for covering said first electrode and said second electrode;
forming a contact hole so as to penetrate said organic insulation film and said inorganic insulation film positioned in said second region, and reach said pad portion positioned in said second region; and
forming a conductive film on an upper surface of said pad portion positioned in a bottom portion of said contact hole so as to be positioned at a distance from a part defined by said organic insulation film in an inner periphery surface of said contact hole.

12. The method for manufacturing the active matrix substrate according to claim 11, further comprising the step of:
lowering a height of said organic insulation film in said second region compared to a height of said organic insulation film in said first region.

13. The method for manufacturing the active matrix substrate according to claim 11, wherein
said organic insulation film serves as a color film,
a step of forming a protective film on said organic insulation film is further provided, and
said contact hole is formed after said protective film has been formed.
